(19) United States
(12) Patent Application Publication
(10) Pub. No.: US 2005/0000447 A1
(43) Pub. Date: Jan. 6, 2005

(54) Crucible for evaporation of raw materials

(76) Inventors: Jan Koninckx, Mol (BE); Luc Struye, Mortsel (BE); Johan Lamotte, Rotselaar (BE)

Correspondence Address: Joseph T. Guy Ph.D.;Nexsen Pruet Jacobs & Pollard LLP, 201 W. McBee Avenue, Greenville, SC, 29603, US

(21) Appl. No.: 10/885,335

(22) Filed: Jul. 6, 2004

Related U.S. Application Data
(60) Provisional application No. 60/501,209, filed on Sep. 8, 2003.

(30) Foreign Application Priority Data
Jul. 4, 2003 (EP) 03102003.5

(51) Int. Cl. C23C 16/00

(52) U.S. Cl. 118/726

(57) ABSTRACT

Crucibles having a bottom and surrounding side walls, provided with electrode clamps at exterior sites of side walls located opposite with respect to each other, wherein said sites are extending as lips at said side walls, and wherein said clamps are connectable with electrodes for heating said crucible, are improved in that a cross-section of each of said lips between between crucible wall and clamp is reduced with at least 5%.

The application claims the benefit of U.S. Provisional application No. 60/501,209 file Sep. 08, 2003

### FIELD OF THE INVENTION

The present invention relates to an improved crucible as a solution for uniformly heating said crucible, which is suitable for use in an evaporation process of raw materials for a vapor deposition.

### BACKGROUND OF THE INVENTION

A physical vapor deposition (PVD) process as e.g. for the preparation of photostimulable phosphors has been described in WO 01/03156. The use of alkali metal halide phosphors in storage screens or panels is well known in the art of storage phosphor radiology and the high crystal symmetry of these phosphors makes it possible to provide structured screens and binderless screens.

It has been disclosed that when binderless screens with an alkali halide phosphors are produced it is beneficial to have the phosphor crystal deposited as some kind of piles, needles, tiles, etc. So in U.S. Pat. No. 4,769,549 it has been disclosed that the image quality of a binderless phosphor screen can be improved when the phosphor layer has a block structure shaped in fine pillars. In U.S. Pat. No. 5,055,681 a storage phosphor screen comprising an alkali halide phosphor in a pile-like structure has e.g. been disclosed. Measures in order to improve the image quality of such screens with pillar-like phosphors by reducing its roughness in that a levelling of that surface increases its sharpness have been developed and e.g. in U.S. Pat. No. 5,874,744 attention has been drawn to the index of refractivity of the phosphor used to produce the storage phosphor screen with needle-like of pillar-like phosphor. Further developments in order to fulfill the need for X-ray images with good quality, the need for a better compromise between speed of the recording system (i.e. as low as possible patient dose) with an image with high sharpness and low noise have been described in EP-A's 1 113 458 and 1 217 633.

Binderless screens may thus be prepared by bringing the finished phosphor on a support by any method selected from the group consisting of physical vapor deposition, thermal vapor deposition, chemical vapor deposition, electron beam deposition, radio frequency deposition and pulsed laser deposition. As set out in the EP-A's 1 113 458 and 1 217633, it is possible to bring an alkali metal halide and a dopant together in a crucible as a mixture of raw materials and to deposit them both by vapor deposition on a support in such a way that the alkali metal phosphor is doped during the manufacture of the screen. The binderless screen has been described therein as being prepared by bringing the finished phosphor on the support by any method selected from the group consisting of physical vapor deposition, thermal vapor deposition, chemical vapor deposition, electron beam deposition, radio frequency deposition and pulsed laser deposition. It is also possible to bring the alkali metal halide and the dopant together and depositing them both on the support in such a way that the alkali metal phosphor is doped during the manufacture of the screen. A method for manufacturing a phosphor screen has thus been described, said method providing a CsX:Eu stimulable phosphor, wherein X represents a halide selected from the group consisting of Br and Cl, wherein the method was characterized by the steps of bringing multiple containers of said CsX and an Europium compound selected from the group consisting of EuX′₂, EuX′₃ and EuOX′, X′ being a halide selected from the group consisting of F, Cl, Br and I in condition for vapor deposition and depositing, by a method selected from the group consisting of physical vapor deposition, thermal vapor deposition, chemical vapor deposition, electron beam deposition, radio frequency deposition and pulsed laser deposition, both said CsX and said Europium compound being deposited on a substrate in such a ratio that a CsX phosphor, doped with between 10⁻³ and 5 mol % of Europium was formed.

Even if all measures possible were taken in order to get an optimized vaporization of the raw materials from elongated crucibles by electric heating of the said crucibles, it has been shown that it remains difficult to get homogeneous deposits of doped alkali halide phosphors onto cooled supports or substrates, whereupon the deposition has been performed.

### OBJECTS AND SUMMARY OF THE INVENTION

It is a first object to provide an elongated refractory crucible providing more homogeneous electric resistance heating of said crucible via conducting clamps, positioned at exterior sites thereof, in order to get homogeneous deposits of layers from evaporated raw materials. Although more generally applicable, more in particular, homogeneous deposit of doped alkali halide phosphors onto cooled supports or substrates is envisaged.

It is a further object of the present invention to provide a phosphor screen, and more preferably a stimulable phosphor screen useful in an X-ray recording system, wherein said screen shows an excellent homogeneity of the phosphor layer composition and a very good and constant speed of the recording system (in order to reduce patient dose to an amount as low as possible), and an image with high, constant sharpness and low, constant noise over the whole screen or panel surface.

The above mentioned object to provide a stimulable phosphor screen having a homogeneous phosphor composition has been realized now by preparing said layer from a mixture of raw materials, and by evaporating said mixture in a newly designed refractory crucible by physical vapor deposition onto a cooled substrate support, while taking into account the specific features for the crucible as defined in claim 1. Specific features for preferred embodiments of the invention are disclosed in the dependent claims.

Further advantages and embodiments of the present invention will become apparent from the following description and drawings.

### BRIEF DESCRIPTION OF THE DRAWINGS

FIG. 1 shows two crucibles, one of which shows the prior art without notches, whereas the inventive elongated crucible is characterized by presence of such notches, reducing the cross-section of each of said lips between between crucible wall and electrode clamp is reduced with at least 5%.

### DETAILED DESCRIPTION OF THE INVENTION

As is well-known from the cited prior art, the container(s) or crucible(s) with starting materials is (are) normally heated up to a temperature exceeding the melting temperature of the starting raw materials, without however being limitative for the present invention, as temperature may be higher or lower, depending upon the requirements in order to get vaporization conditions, thus leading to homogeneous depositions.

It is clear that material compositions of crucibles should be resistant to physical influences, in that the materials should be refractory materials. Desired refractory materials are chosen therefore selected from the group of materials consisting of Mo, Nb, Ta and W. An ultimate choice of a suitable material for use as a refractory material mostly depends on its manutention as the crucibles should be brought into the desired form (e.g. deformation by folding or bending of plates of the desired thickness in a so-called “nip-zone” or between rollers or other “flattening means” in order to be used as a container of raw materials to be vaporized. It is clear that only the raw material(s) contained in the crucibles or boats should melt at the designed process temperatures in order to be vaporized and deposited afterwards onto a cooled substrate.

Formation of e.g. mixed melt crystals of crucible material and raw materials contained in the crucibles should clearly not be appreciated as a source of undesired contamination. Besides being physically inert, it is clear that the crucible material should be chemically inert, in that chemical reactions between same contacting raw materials and crucible materials should be about impossible, as otherwise the composition of the deposition product onto the cooled substrate would not be controlled. Besides such an uncontrollable composition, homogeneity or uniformity of the deposited layers should be out of controll.

Apart from its desired inert properties, from a physical as well as from a chemical point of view, it has been shown that even if all measures have been taken in order to avoid sputtering of heated raw material from crucibles or boats carrying raw materials or mixtures thereof, inhomogeneous heating of raw materials in crucibles is, at least in part, an important factor to take care of. The problem moreover depends on the form of the boats or crucibles used and the way of heating: as elongated boats are, in most cases, electrically heated, it is clear that the present invention was related with investigations for taking measures in order to provoke more homogeneous heating of such elongated crucibles.

So it has unexpectedly been found in the present invention that means in order to reduce the cross-section of the lips between between crucible wall and electrode clamp with at least 5%, by providing each lip with perforations, provides ability to provoke a more homogeneous electrical resistance heating of said crucible. In one embodiment for the crucible according to the present invention, each lip thus has two notches, reducing in the cross-section between crucible wall and electrode clamp the width of the lips with at least 5%, and more preferably even with at least 10%.

Furtheron the crucible according to the present invention has electrode clamps, wherein said clamps are clamping said upper lips such that a surface in the range from 10% to 100% of each upper lip is covered by each clamp. Contact with clamps at exterior sites thereof, wherein said sites are extending as upper lips at the smallest side walls of said crucible (in case of an elongate crucible) thus, in one embodiment, provides that the said clamps are clamping said upper lips such that at least one half (½) of each upper lip is covered by each clamp and that each lip has two notches, reducing contact of each upper lip over each of said smallest side walls to an extent as claimed.

This effect attained by the measures as set out above may be interpreted as due to the creation of a higher local temperature, whereas in the crucible designed as in the prior art, loss in temperature or undesired local gradients may cause undesired inhomogeneities (local whirlings) in the physical vaporization conditions and, as a consequence thereof, in the deposition at the cooled substrate support, whereupon the material has to be vapor deposited. Experimental evidence in order to support this statement is found in the observation, at “inventive crucibles”, of absence of “raw material”, “creeping” out of the crucibles on top of the side walls, while this was clearly observed for “prior art crucibles” without reduced cross-section between side walls and electrode clamps.

According to the present invention a crucible having a bottom and surrounding side walls provided with clamps at exterior sites of side walls located opposite with respect to each other and wherein said clamps are connectable with electrodes for heating said crucible, is characterized in that a cross-section of said lips between between crucible wall and clamp is reduced with at least 10%. In this more preferred embodiment according to the present invention in the cross-section, the width of the lips of the crucible is reduced with at least 5%, and more preferably with at least 10%, by presence of notches.

According to the present invention, in one embodiment the crucible it is in form of a square. In this case, a ratio between side walls surrounding the bottom of said crucible is 1:1.

According to the present invention, in another embodiment, the crucible has such dimensions that a ratio between largest and smallest side walls surrounding the bottom of said crucible is in the range from 1:1 up to 100:1, and more preferably at least 1.5:1.

More preferably for said crucible according ot the present invention a ratio between the largest and smallest side walls surrounding the bottom of said crucible is in the range from 2:1 to 50:1, and even more preferably said ratio is in the range from 2:1 up to 10:1.

It is clear that in practice crucibles have dimensions adapted to the vapor deposition unit wherein those crucibles are used. As disclosed e.g. in EP-Applications Nos. 03 100 723, filed Mar. 20, 2003, and 04 101 138, filed Mar. 19, 2004, dimensions of the crucible therein were 0.97 m (length)×4.5 cm (width)×6.8 cm (depth), having a wall thickness of 3 mm), in which 4 kg of a mixture of CsBr and EuOBr in a 99,5%/0,5% CsBr/EuOBr percentage ratio by weight were present as raw materials to become vaporized.

According to the present invention said crucible is composed of a refractory material, conducting electricity.

In a preferred embodiment the crucible according to the present invention is composed of a refractory material, being a metal or metal alloy selected from the group consisting of tantalum (Ta), molybdene (Mo), niobium (Nb), tungsten (W) and heat-resistant stainless steel, wherein the said refractory material is covered with a silicide layer or a carbide layer of said metal or metal alloy.

It is clear that this layer should be very thin (in the order of micrometers) in order to avoid reduced conductivity (of electricity and heat) while heating.

The crucible according to the present invention further has side walls having a thickness of not more than 3 mm. More preferably the crucible has side walls having a thickness of not more than 2 mm. In practice said thickness is in the range from 0.1 mm (for small crucibles) up to 3 mm (for very large, e.g., elongated crucibles in view of strength), but more preferably from 0.1 mm to 2 mm (in view of rapid homogeneous heating of its contents), and even up to 1.5 mm in a most preferred embodiment.

For the crucible according to the present invention, said clamps are made of copper as copper indeed is a metal, well-known for its very good conductivity for heat and electricity.

An evaporation method by electric resistance heating of a crucible according to the present invention is further disclosed, wherein said crucible is filled with raw materials up to at most 80% of its total volume, and more preferably up to at most 50%, said volume being determined by the inner surface of its bottom and height of its inner side walls and wherein electric heating proceeds up to a temperature exceeding the melting temperature of said raw materials with at least 10° C. above the melting temperature of said raw materials.

The evaporation method according to the present invention is preferably performed so that electric heating proceeds up to a temperature exceeding the melting temperature of said raw materials in the range from 20° C. up to 100° C. above the melting temperature of said raw materials. In this case said crucible is filled with raw materials up to at most 50% of its total volume (especially in order to avoid sputtering e.g.).

The evaporation method according to the present invention is moreover performed with raw materials selected from the group consisting of alkali halides, earth alkali halides, halides, oxides or oxihalides of earth metals; halides, oxides or oxihalides of the group of elements of the lanthanide series and combinations thereof.

The evaporation can proceed from a single container containing a mixture of the starting compounds in the desired proportions or from a series of containers, trays, boats (as terms used as synonyms for the word “crucible”) or crucibles as has e.g. been described in EP-Applications Nos. 03 100 723, filed Mar. 20, 2003 and 04 101 138, filed Mar. 19, 2004. In that invention a method for coating a phosphor or a scintillator layer onto a flexible substrate has been presented, within a sealed zone maintained under vacuum conditions, by the step of vapor deposition, wherein said phosphor or scintillator layer is, continuously or discontinuously, deposited onto said substrate, and wherein said substrate is deformed at least before, during or after said step of vapor deposition, in order to provide the manufacturer, by a process of exceptionnally high yield, with large deposited phosphor or a scintillator sheets having constant speed and image quality properties, further offering availablity of all formats as desired for screens, plates or panels ready-for-use in a scanning apparatus in computed radiography, screen/film radiography and direct radiography. As preparation of large surfaces coated with phosphor or scintillator layers,in this case is envisaged, it it clear that homogeneity of phosphor composition and thickness over those large surfaces is of utmost importance.

In a common arrangement within a sealed zone under vacuum pressure (vacuum conditions corresponding with at least 10⁻¹ mbar, and even down to 10⁻⁴ mbar or less if attainable in such a configuration), the crucible preferably is in form of an elongated “boat”. In another embodiment it is composed of a plurality of crucibles, arranged in order to coat a complete substrate support (in most cases an aluminum support, and, even more preferably an anodized aluminum layer). It is evident that the composition of the raw material in the containers is chosen in order to provide a composition as desired, wherein said composition is determined by the ratios of raw materials present. Ratios of raw materials are chosen in order to provide the desired chemical phosphor or scintillator composition after deposition of the vaporized raw materials. It is desirable to mix the raw materials in order to get a homogeneous raw mix in the crucible(s) in form of solid powders, grains or granules, or as pastilles having a composition corresponding with the desired ratios of raw materials in order to provide the desired phosphor coated onto the moving substrate material. A milling procedure may be favorable in order to provide a high degree of homogeneity before vaporization and is therefore recommended. Differing components may also be vaporized from different crucibles, arranged in series or in parallel or in a combined arrangement as already suggested before, provided that a homogeneous vapor cloud is presented to the flexible substrate via the vapor stream or flow, deposited by condensation onto said substrate. Two elongated one-part boats having same or different raw material content or raw material mixtures may e.g. be present in series in the moving direction of the web. In another embodiment, if providing a more homogeneous coating profile, boats may be arranged in parallel on one axis or more axes, perpendicular to the moving direction of the support, provided that overlapping evaporation clouds again are providing a vapor stream that becomes deposited onto the support in a phosphor or scintillator layer having a homogeneous thickness, composition and coated amount of phosphor or scintillator. Presence of more than one crucible may be in favor of ability to supply greater amounts of phosphor or scintillator material to be deposited per time unit, the more when the flexible substrate should pass the vapor flow at a rate, high enough in order to avoid too high temperature increase of the substrate. The velocity or rate at which the substrate passes the container(s) as mentioned in the on-line deposition procedure set out in EP-Applications Nos. 03 100 723, filed Mar. 20, 2003, and 04 101 138, filed Mar. 19, 2004, should indeed not be too slow in view of undesired local heating of the substrate support, making deposition impossible, unless sufficient cooling means are present in favor of condensation. The supporting or supported substrate should therefore preferably have a temperature between 50° C. and 300° C. in order to obtain deposited phosphor or scintillator layers having the desired optimized properties.

As already mentioned hereinbefore energy should be supplied to one or more crucibles(), in order to provoke a homogeneous vapor flow (or stream) of the raw materials present therein, which become vaporized in the sealed vacuum zone. As already set forth electric energy is commonly provided by resistive heating, making use of crucibles according to the present invention, thereby providing homogeneous heat transfer to the containers or crucibles and to their contents, being the raw materials that should be evaporated. In practice energy is supplied to an extent in order to heat the container(s) or crucible(s) up to a temperature above 450° C., preferably above 550° C., and even more preferably in the range of 550° C. up to 900° C.

A cloud of vaporized material, originating from the target raw materials thus escapes as a cloud in form of a flow or stream from the container(s) or crucible(s) in the direction of the substrate, where a coated layer is formed by condensation, which only applies if the temperature of the substrate is lowered in order to provoke condensation. From the description above it is clear that, in order to obtain a homogeneous coating profile as envisaged, a homogeneous cloud can only be realized when homogeneity is provided in the bulk of the liquefied raw material. As a consequence, a homogeneous distribution of energy supplied over the container is a stringent demand, that is advantageously realized by use of crucibles according to the present invention. In a preferred embodiment, in favor of homogeneity, the crucible is in form of a single elongated “boat” with a largest dimension corresponding with the width of the support, and, in case of “on-line deposition”, a flexible support is moving over the said crucible according to the present invention, so that at each point of its surface area the momentarily velocity magnitude is constant.

In any configuration providing the possibility for the substrate support to pass the raw material container(s) more than once, more than one phosphor or scintillator layer is optionally deposited, if desired. Addition to the crucible(s) of raw materials determining, and, optionally, changing the chemical composition of the scintillator to be deposited in the vapor deposition process, provides the possibility to gradually change the phosphor or scintillator composition in thickness direction of the deposited layer.

Even when no change in composition in the thickness direction is desired, it is clear that the raw material(s) contained in the crucible(s) become(s) exhausted during the physical vapor deposition process, set forth hereinbefore. Therefore “replenishment” of the crucible(s) should be provided, e.g. by addition of raw material components in powdery form, in form of grains or crystals or in form of pastilles containing caked powder or grain mixtures, in favor of maintaining homogeneity during the further evaporation process as otherwise, differences in dopant (Europium) concentrations may appear while the coating process is running furtheron. Methods in order to “replenish” the crucible(s) have e.g. been described in U.S. Pat. No. 4,430,366, in DE-A 1 98 52362 and in US-A 2003/0024479 A1.

An annealing step inbetween two deposition steps and/or at the end of the phosphor deposition may be benificial. During such an annealing step cooling the phosphor or scintillator layer (e.g. up to room temperature), bringing said phosphor or scintillator layer up to a temperature between 80 and 200° C. and maintaining it at that temperature for between 10 minutes and 15 hours may be performed as disclosed in the published US-Application 2003/0104121 A1.

Factors providing deposition of homogeneous phosphor or scintillator coating composition and thickness of the layers, besides use of crucible(s) according to the present invention are related with the distance determining the profile of the vapor cloud at the position of the flexible substrate. Average values of shortest distances between crucible(s) and substrate are preferably in the range of from 5 to 10 cm. Too large distances would lead to loss of material and decreased yield of the process, whereas too small distances would lead to too high a temperature of the substrate.

Care should further be taken with respect to avoiding “spot errors” or “pits”, resulting in uneven deposit of phosphors or scintillators, due to spitting of the liquefied raw materials present in the heated container(s), tray(s) or boat(s). One way to avoid spots to reach the moving web or support is to provide the container(s) with a metallic raster, supported by the surrounding edges of said container(s) and covering, at least in part, the container(s). Different configurations are available in order to get the most advantageous solution in order to avoid those spot defects. Even when very small holes are present in the panel, covering the crucible according to the present invention, “spot errors” or “pits” may still disturb the uniformity of the pattern of the deposited layer. A solution therefor is attained by mounting a second cover having small holes (whether or not having an identical hole pattern over its surface) at a distance farther from the crucible, wherein, after having mounted both covers having hole patterns at both surfaces, both covers are located so that the holes will never overlap each other completely when viewed from a direction perpendicular to the surface of the outermost cover, and more preferably located so that the bottom of the crucible or its contents can never be observed.

Apart from a cover without holes, preferably present as an outermost cover while heating the crucible before an optimized and constant high temperature has been reached in order to evaporate the raw materials in a “steady-state” flow, a guiding plate, guiding one or more vapor stream(s) towards the substrate may be present in order to more sharply define the region wherein phosphor or scintillator material should become deposited. So presence of a baffle advantageously restricts the vapor deposition region on the substrate to a small segment or sector, in order to prevent undesired deposition of scintillator material as e.g. on the wall of the deposition chamber.

Preferred phosphors of the alkali metal storage type to be deposited are e.g. those having been described in U.S. Pat. No. 5,736,069. That phosphor is disclosed as having the general formula given hereinafter:
M¹⁺X.aM²⁺X′₂.bM³⁺X″₃:cZ
wherein: M¹⁺ is at least one member selected from the group consisting of Li, Na, K, Cs and Rb,
M²⁺ is at least one member selected from the group consisting of Be, Mg, Ca, Sr, Ba, Zn, Cd, Cu, Pb and Ni,
M³⁺ is at least one member selected from the group consisting of Sc, Y, La, Ce, Pr, Nd, Pm, Sm, Eu, Gd, Tb, Dy, Ho, Er, Tm, Yb, Lu, Al, Bi, In and Ga,
Z is at least one member selected from the group Ga¹⁺, Ge²⁺, Sn²⁺, Sb³⁺and As³⁺,
X, X′ and X″ may be the same or different and each represents a halogen atom selected from the group consisting of F, Br, Cl, and I, and 0≦a≦1, 0≦b≦1 and 0<c≦0.2.

Besides screens or panels the phosphor layers of which have a composition as disclosed hereinbefore a phosphor screen containing a CsX:Eu stimulable phosphor, wherein X represents a halide selected from the group consisting of Br and Cl is highly desired.

Preparation steps in order to manufacture such screens or panels have been described in WO 01/03156. In favor of image sharpness needle shaped Eu-activated alkali metal halide phosphors, and more particularly, Eu-activated CsBr phosphor screens as described in EP-A 1 113 458 are preferred and, in view of an improved sensitivity, annealing of said phosphors as in EP-A 1 217 633 is advantageously performed, said annealing step consisting of bringing the cooled deposited mixture as deposited on the substrate to a temperature between 80 and 220° C. and maintaining it at that temperature for between 10 minutes and 15 hours.

The high degree of crystallinity is easily analysed by X-ray diffraction techniques, providing a particular XRD-spectrum as has been illustrated in EP-A 1 113 458. Therefore a mixture of CsBr and EuOBr is provided as a raw material mixture in the crucibles, wherein a ratio between both raw materials normally is about 90% by weight. The high degree of crystallinity is easily analysed by X-ray diffraction techniques, providing a particular XRD-spectrum as has been illustrated in EP-A 1 113 458. Therefore a mixture of CsBr and EuOBr or EuBr₃ is provided as a raw material mixture in the crucibles, wherein a ratio between both raw materials normally is about 90% by weight of the cheap CsBr and 10% of the expensive EuOBr, both expressed as weight %. It has however been shown that as a function of coating (evaporating) temperature ratios can be adapted in favor of lower material and production cost, without resulting in changes in composition: so higher vaporization temperatures for the raw material mixture in ratio amounts of 99.5 wt % CsBr and 0.5 wt % EuOBr provide the same result (related with speed) as before. Such a process obviously leads to a more homogeneously divided phosphor layer and a lower amount of Eu-dopant. Screens of CsBr: Eu²⁺ phosphors having lower amounts of Europium dopant, i.a. in the range from 100-200 p.p.m. versus at least 500-800 p.p.m. (see Examples in EP-A 1 113 458-phosphor layers prepared therein in the absence however of the crucibles according to the present invention). These data are suggesting that the presence of lower amounts of Europium dopant, nevertheless leading to the same screen speed, is indicative for a more homogeneous distribution and/or more efficient built-in of the dopant. Opposite thereto screens requiring an amount of dopant in the range from 1000 p.p.m., and even up to 3000 p.p.m., are indicating that dopants do not seem to have been built in efficiently. From the examples in EP-A 1 113 458 CsBr:Eu it has been learnt that screens were made via thermal vapor deposition of CsBr and EuOBr (and/or EuBr₃)and that variables in the deposition process were the substrate temperature and the Ar gas pressure, leading to needle-shaped crystals having characteristic high intensity for the [100] crystal plane in XRD-spectra thereof.

### EXAMPLES

While the present invention will hereinafter be described in connection with preferred embodiments thereof, it will be understood that it is not intended to limit the invention to those embodiments.

“Prior art crucibles” are not provided with notches in the cross-section region of the upper lips between side wall and electrode clamp of the crucible, wherein moreover each lip is provided with perforations. These crucibles are heated less homogeneously as at the clamping site, between clamp parts, the temperature is lower than for all other sites of the crucible, once the process of evaporation of raw materials starts. This is even the case when an equilibrium has been reached and as is clear, an inhomogeneous heating of the crucible appears, as well as an inhomogeneous deposit of evaporated raw materials. Moreover an enhanced danger for “spitting” of the liquefied raw materials is present.

Opposite thereto the crucibles of the present invention, having notches and perforations as set out above in the detailed description, are heated in a more homogeneous way: presence of notches and perforations avoids cooling by the clamps as effects correlated with their mass are significantly reduced by presence of the notches and perforations, as an equal amount of energy (electrical power) is passing through a smaller crucible section.

The electrical resistance for both crucibles (prior art and invention) can be expressed as:

$$R = \frac{L \times ϕ}{A}$$

R=Resistance (Ω)
L=Length of the conductive part (m)
A=Surface of the cross-section (mm²)
Φ=Specific resistance (Ω mm²/m)

Heat development in this cross-section is represented by the expression:

$$H = U \times I \times t \\ = {I}^{2} \times R \times t$$

H=Heat development (in Joule)
U=Voltage (in Volts)
I=Electrical current (in Ampere)
t=Time (in seconds)

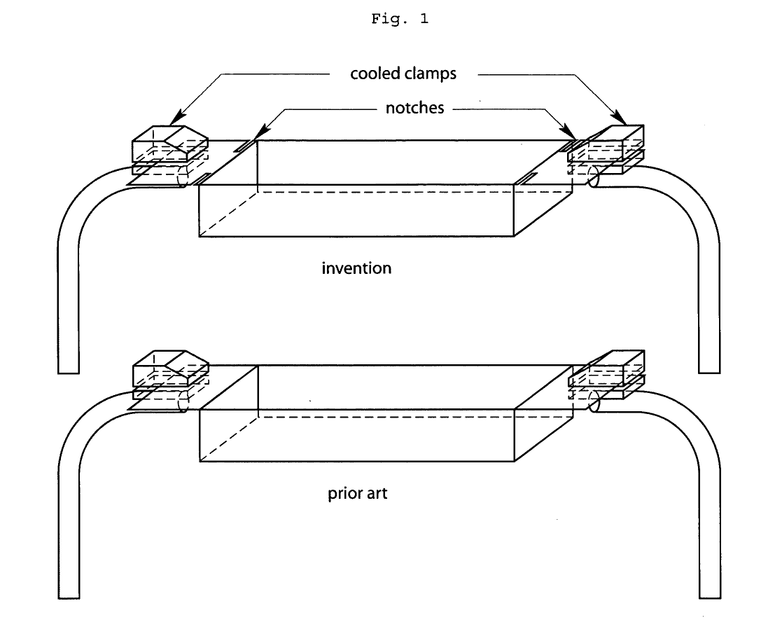

Experimentally it has been observed at “prior art crucibles” without reduced cross-section between side walls and electrode clamps (as shown in FIG. 1) that liquefied raw material creeps out of the crucibles on top of the side walls. At “inventive crucibles” no such undesired phenomenon (from a point of view of loss of raw material and yield of the deposition process) is observed and a desired predetermined evaporating direction is guaranteed.

Having described in detail preferred embodiments of the current invention, it will now be apparent to those skilled in the art that numerous modifications can be made therein without departing from the scope of the invention as defined in the appending claims.

1. Crucible having a bottom and surrounding side walls provided with electrode clamps at exterior sites of side walls located opposite with respect to each other, wherein said sites are extending as lips at said side walls, and wherein said clamps are connectable with electrodes for heating said crucible, characterized in that a cross-section of each of said lips between between crucible wall and electrode clamp is reduced with at least 5%, by providing each lip with perforations.

2. Crucible according to claim 1, wherein said cross-section is reduced by further providing each lip with notches.

3. Crucible according to claim 1, wherein the said clamps are clamping said upper lips such that a surface in the range of from 10% to 100% of each upper lip is covered by each clamp.

4. Crucible according to claim 2, wherein the said clamps are clamping said upper lips such that a surface in the range of from 10% to 100% of each upper lip is covered by each clamp.

5. Crucible according to claim 1, wherein a ratio between side walls surrounding the bottom of said crucible is in the range from 1:1 up to 100:1.

6. Crucible according to claim 2, wherein a ratio between side walls surrounding the bottom of said crucible is in the range from 1:1 up to 100:1.

7. Crucible according to claim 3, wherein a ratio between side walls surrounding the bottom of said crucible is in the range from 1:1 up to 100:1.

8. Crucible according to claim 4, wherein a ratio between side walls surrounding the bottom of said crucible is in the range from 1:1 up to 100:1.

9. Crucible according to claim 1, wherein a ratio between side walls surrounding the bottom of said crucible is in the range from 2:1 up to 10:1.

10. Crucible according to claim 2, wherein a ratio between side walls surrounding the bottom of said crucible is in the range from 2:1 up to 10:1.

11. Crucible according to claim 3, wherein a ratio between side walls surrounding the bottom of said crucible is in the range from 2:1 up to 10:1.

12. Crucible according to claim 4, wherein a ratio between side walls surrounding the bottom of said crucible is in the range from 2:1 up to 10:1.

13. Crucible according to claim 1, wherein said crucible is composed of a refractory material, conducting electricity, wherein said refractory material is a metal or metal alloy, covered with a silicide layer or a carbide layer of said metal or metal alloy.

14. Crucible according to claim 2, wherein said crucible is composed of a refractory material, conducting electricity, wherein said refractory material is a metal or metal alloy, covered with a silicide layer or a carbide layer of said metal or metal alloy.

15. Crucible according to claim 3, wherein said crucible is composed of a refractory material, conducting electricity, wherein said refractory material is a metal or metal alloy, covered with a silicide layer or a carbide layer of said metal or metal alloy.

16. Crucible according to claim 4, wherein said crucible is composed of a refractory material, conducting electricity, wherein said refractory material is a metal or metal alloy, covered with a silicide layer or a carbide layer of said metal or metal alloy.

17. Crucible according to claim 5, wherein said crucible is composed of a refractory material, conducting electricity, wherein said refractory material is a metal or metal alloy, covered with a silicide layer or a carbide layer of said metal or metal alloy.

18. Crucible according to claim 6, wherein said crucible is composed of a refractory material, conducting electricity, wherein said refractory material is a metal or metal alloy, covered with a silicide layer or a carbide layer of said metal or metal alloy.

19. Crucible according to claim 9, wherein said crucible is composed of a refractory material, conducting electricity, wherein said refractory material is a metal or metal alloy, covered with a silicide layer or a carbide layer of said metal or metal alloy.

20. Crucible according to claim 10, wherein said crucible is composed of a refractory material, conducting electricity, wherein said refractory material is a metal or metal alloy, covered with a silicide layer or a carbide layer of said metal or metal alloy.

21. Crucible according to claim 13, wherein said refractory material is a metal or metal alloy selected from the group consisting of tantalum (Ta), molybdene (Mo), niobium (Nb), tungsten (W) and heat-resistant stainless steel.

22. Crucible according to claim 14, wherein said refractory material is a metal or metal alloy selected from the group consisting of tantalum (Ta), molybdene (Mo), niobium (Nb), tungsten (W) and heat-resistant stainless steel.

23. Crucible according to claim 15, wherein said refractory material is a metal or metal alloy selected from the group consisting of tantalum (Ta), molybdene (Mo), niobium (Nb), tungsten (W) and heat-resistant stainless steel.

24. Crucible according to claim 16, wherein said refractory material is a metal or metal alloy selected from the group consisting of tantalum (Ta), molybdene (Mo), niobium (Nb), tungsten (W) and heat-resistant stainless steel.

25. Crucible according to claim 17, wherein said refractory material is a metal or metal alloy selected from the group consisting of tantalum (Ta), molybdene (Mo), niobium (Nb), tungsten (W) and heat-resistant stainless steel.

26. Crucible according to claim 18, wherein said refractory material is a metal or metal alloy selected from the group consisting of tantalum (Ta), molybdene (Mo), niobium (Nb), tungsten (W) and heat-resistant stainless steel.

27. Crucible according to claim 19, wherein said refractory material is a metal or metal alloy selected from the group consisting of tantalum (Ta), molybdene (Mo), niobium (Nb), tungsten (W) and heat-resistant stainless steel.

28. Crucible according to claim 20, wherein said refractory material is a metal or metal alloy selected from the group consisting of tantalum (Ta), molybdene (Mo), niobium (Nb), tungsten (W) and heat-resistant stainless steel.

29. Crucible according to claim 1, wherein said side walls have a thickness of up to 3 mm.

30. Crucible according to claim 2, wherein said side walls have a thickness of up to 3 mm.

31. Crucible according to claim 3, wherein said side walls have a thickness of up to 3 mm.

32. Crucible according to claim 4, wherein said side walls have a thickness of up to 3 mm.

33. Crucible according to claim 5, wherein said side walls have a thickness of up to 3 mm.

34. Crucible according to claim 6, wherein said side walls have a thickness of up to 3 mm.

35. Crucible according to claim 7, wherein said side walls have a thickness of up to 3 mm.

36. Crucible according to claim 8, wherein said side walls have a thickness of up to 3 mm.

37. Crucible according to claim 13, wherein said side walls have a thickness of up to 3 mm.

38. Crucible according to claim 14, wherein said side walls have a thickness of up to 3 mm.

39. Crucible according to claim 15, wherein said side walls have a thickness of up to 3 mm.

40. Crucible according to claim 16, wherein said side walls have a thickness of up to 3 mm.

41. Crucible according to claim 1, wherein said side walls have a thickness in the range from 0.1 mm up to 2 mm.

42. Crucible according to claim 2, wherein said side walls have a thickness in the range from 0.1 mm up to 2 mm.

43. Crucible according to claim 3, wherein said side walls have a thickness in the range from 0.1 mm up to 2 mm.

44. Crucible according to claim 4, wherein said side walls have a thickness in the range from 0.1 mm up to 2 mm.

45. Evaporation method by electric resistance heating of a crucible according to claim 1, wherein said crucible is filled with raw materials up to at most 80% of its total volume, determined by its inner surface of its bottom and height of its inner side walls and wherein electric heating proceeds up to a temperature exceeding the melting temperature of said raw materials with at least 10° C.

46. Evaporation method by electric resistance heating of a crucible according to claim 2, wherein said crucible is filled with raw materials up to at most 80% of its total volume, determined by its inner surface of its bottom and height of its inner side walls and wherein electric heating proceeds up to a temperature exceeding the melting temperature of said raw materials with at least 10° C.

47. Evaporation method by electric resistance heating of a crucible according to claim 3, wherein said crucible is filled with raw materials up to at most 80% of its total volume, determined by its inner surface of its bottom and height of its inner side walls and wherein electric heating proceeds up to a temperature exceeding the melting temperature of said raw materials with at least 10° C.

48. Evaporation method by electric resistance heating of a crucible according to claim 4, wherein said crucible is filled with raw materials up to at most 80% of its total volume, determined by its inner surface of its bottom and height of its inner side walls and wherein electric heating proceeds up to a temperature exceeding the melting temperature of said raw materials with at least 10° C.

49. Evaporation method by electric resistance heating of a crucible according to claim 5, wherein said crucible is filled with raw materials up to at most 80% of its total volume, determined by its inner surface of its bottom and height of its inner side walls and wherein electric heating proceeds up to a temperature exceeding the melting temperature of said raw materials with at least 10° C.

50. Evaporation method by electric resistance heating of a crucible according to claim 6, wherein said crucible is filled with raw materials up to at most 80% of its total volume, determined by its inner surface of its bottom and height of its inner side walls and wherein electric heating proceeds up to a temperature exceeding the melting temperature of said raw materials with at least 10° C.

51. Evaporation method by electric resistance heating of a crucible according to claim 7, wherein said crucible is filled with raw materials up to at most 80% of its total volume, determined by its inner surface of its bottom and height of its inner side walls and wherein electric heating proceeds up to a temperature exceeding the melting temperature of said raw materials with at least 10° C.

52. Evaporation method by electric resistance heating of a crucible according to claim 8, wherein said crucible is filled with raw materials up to at most 80% of its total volume, determined by its inner surface of its bottom and height of its inner side walls and wherein electric heating proceeds up to a temperature exceeding the melting temperature of said raw materials with at least 10° C.

53. Evaporation method by electric resistance heating of a crucible according to claim 1, wherein said crucible is filled with raw materials up to at most 50% of its total volume, determined by its inner surface of its bottom and height of its inner side walls and wherein electric heating proceeds up to a temperature exceeding the melting temperature of said raw materials in the range from 20° C. up to 100° C. above the melting temperature of said materials.

54. Evaporation method by electric resistance heating of a crucible according to claim 2, wherein said crucible is filled with raw materials up to at most 50% of its total volume, determined by its inner surface of its bottom and height of its inner side walls and wherein electric heating proceeds up to a temperature exceeding the melting temperature of said raw materials in the range from 20° C. up to 100° C. above the melting temperature of said materials.

55. Evaporation method by electric resistance heating of a crucible according to claim 3, wherein said crucible is filled with raw materials up to at most 50% of its total volume, determined by its inner surface of its bottom and height of its inner side walls and wherein electric heating proceeds up to a temperature exceeding the melting temperature of said raw materials in the range from 20° C. up to 100° C. above the melting temperature of said materials.

56. Evaporation method by electric resistance heating of a crucible according to claim 4, wherein said crucible is filled with raw materials up to at most 50% of its total volume, determined by its inner surface of its bottom and height of its inner side walls and wherein electric heating proceeds up to a temperature exceeding the melting temperature of said raw materials in the range from 20° C. up to 100° C. above the melting temperature of said materials.

57. Evaporation method by electric resistance heating of a crucible according to claim 5, wherein said crucible is filled with raw materials up to at most 50% of its total volume, determined by its inner surface of its bottom and height of its inner side walls and wherein electric heating proceeds up to a temperature exceeding the melting temperature of said raw materials in the range from 20° C. up to 100° C. above the melting temperature of said materials.

58. Evaporation method by electric resistance heating of a crucible according to claim 6, wherein said crucible is filled with raw materials up to at most 50% of its total volume, determined by its inner surface of its bottom and height of its inner side walls and wherein electric heating proceeds up to a temperature exceeding the melting temperature of said raw materials in the range from 20° C. up to 100° C. above the melting temperature of said materials.

59. Evaporation method by electric resistance heating of a crucible according to claim 7, wherein said crucible is filled with raw materials up to at most 50% of its total volume, determined by its inner surface of its bottom and height of its inner side walls and wherein electric heating proceeds up to a temperature exceeding the melting temperature of said raw materials in the range from 20° C. up to 100° C. above the melting temperature of said materials.

60. Evaporation method by electric resistance heating of a crucible according to claim 8, wherein said crucible is filled with raw materials up to at most 50% of its total volume, determined by its inner surface of its bottom and height of its inner side walls and wherein electric heating proceeds up to a temperature exceeding the melting temperature of said raw materials in the range from 20° C. up to 100° C. above the melting temperature of said materials.

61. Evaporation method according to claim 53, wherein said raw materials are selected from the group consisting of alkali halides, earth alkali halides, halides, oxides or oxihalides of earth metals; halides, oxides or oxihalides of the group of elements of the lanthanide series and combinations thereof.

62. Evaporation method according to claim 54, wherein said raw materials are selected from the group consisting of alkali halides, earth alkali halides, halides, oxides or oxihalides of earth metals; halides, oxides or oxihalides of the group of elements of the lanthanide series and combinations thereof.

63. Evaporation method according to claim 55, wherein said raw materials are selected from the group consisting of alkali halides, earth alkali halides, halides, oxides or oxihalides of earth metals; halides, oxides or oxihalides of the group of elements of the lanthanide series and combinations thereof.

64. Evaporation method according to claim 56, wherein said raw materials are selected from the group consisting of alkali halides, earth alkali halides, halides, oxides or oxihalides of earth metals; halides, oxides or oxihalides of the group of elements of the lanthanide series and combinations thereof.

65. Evaporation method according to claim 57, wherein said raw materials are selected from the group consisting of alkali halides, earth alkali halides, halides, oxides or oxihalides of earth metals; halides, oxides or oxihalides of the group of elements of the lanthanide series and combinations thereof.

66. Evaporation method according to claim 58, wherein said raw materials are selected from the group consisting of alkali halides, earth alkali halides, halides, oxides or oxihalides of earth metals; halides, oxides or oxihalides of the group of elements of the lanthanide series and combinations thereof.

67. Evaporation method according to claim 59, wherein said raw materials are selected from the group consisting of alkali halides, earth alkali halides, halides, oxides or oxihalides of earth metals; halides, oxides or oxihalides of the group of elements of the lanthanide series and combinations thereof.

68. Evaporation method according to claim 60, wherein said raw materials are selected from the group consisting of alkali halides, earth alkali halides, halides, oxides or oxihalides of earth metals; halides, oxides or oxihalides of the group of elements of the lanthanide series and combinations thereof.
